(19) United States
(12) Patent Application Publication
(10) Pub. No.: US 2025/0157818 A1
(43) Pub. Date: May 15, 2025

(54) LOW VOLUME SHRINKAGE, HIGH ETCH RESISTANCE AND HIGH RESOLUTION PHOTORESISTS

(71) Applicant: Taiwan Semiconductor Manufacturing Co., Ltd., Hsinchu (TW)

(72) Inventors: Jia-Lin WEI, Hsinchu (TW); Ching-Yu CHANG, Hsinchu (TW)

(21) Appl. No.: 18/506,864

(22) Filed: Nov. 10, 2023

(51) Int. Cl. H01L 21/027; G03F 7/038; G03F 7/32; G03F 7/38; H01L 21/311

(52) U.S. Cl. CPC H01L 21/0275; G03F 7/038; G03F 7/325; G03F 7/38; H01L 21/31122; H01L 21/31138; H01L 21/31144

(57) ABSTRACT

A method for forming a semiconductor device is provided. The methods includes forming a photoresist layer over a substrate. The photoresist layer includes a polymer and an photoacid generator (PAG). The polymer includes a polymer backbone, an etch resistance promoting group chemically bonded to the polymer backbone, and an acid labile group (ALG) chemically bonded to the etch resistance promoting group. The method further includes exposing a portion of the photoresist layer to a radiation to produce acid in exposed portion, baking the photoresist layer, resulting in cleavage of the ALG, and removing an portion of the photoresist layer to form a patterned photoresist layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrate a photoresist composition that can be used for forming a photoresist layer, in accordance with some embodiments of the present disclosure.

FIG. 2 is a flow chart of a method for fabricating a semiconductor device, in accordance with some embodiments of the present disclosure.

FIGS. 3A-3E are cross-sectional views of a semiconductor device fabricated using the method of FIG. 2, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When describing the compounds, compositions, methods and processes of the present disclosure, the following terms have the following meanings, unless otherwise indicated.

As described herein, the compounds disclosed herein may optionally be substituted with one or more substituents, such as illustrated generally below, or as exemplified by particular classes, subclasses, and species of the present disclosure. It will be appreciated that the phrase “optionally substituted” is used interchangeably with the phrase “substituted or unsubstituted”. In general, the term “substituted” whether proceeded by the term “optionally” or not, refers to the replacement of one or more hydrogen radicals in a given structure with the radical of a specified substituent. Unless otherwise indicated, an optionally substituted group may have a substituent at each substitutable position of the group. When more than one position in a given structure can be substituted with more than one substituent selected from a specified group, the substituent may be either the same or different at each position.

As used herein, the term “polymer” generally refers to a molecule composed of repeating structural units connected by covalent chemical bonds and characterized by a substantial number of repeating units (e.g., equal to or greater than 20 repeating units and often equal to or greater than 100 repeating units and often equal to or greater than 300 repeating units) and a number average molecular weight greater than or equal to 5,000 Daltons (Da) or 5 kDa, such as greater than or equal to 10 kDa, 15 kDa, 20 kDa, 30 kDa, 40 kDa, 50 kDa, or 100 kDa. Polymers are commonly the polymerization product of one or more monomer precursors. The term polymer includes homopolymers, i.e., polymers consisting of repeating units of a single monomer. The term polymer also includes copolymers which are formed when two or more different types of monomers are linked in the same polymer. Copolymers may comprise two or more monomer subunits, and include random, block, alternating, segmented, grafted, tapered and other copolymers. The term “crosslinked polymers” generally refers to polymers having one or multiple links between at least two polymer chains, which can result from multivalent monomers forming crosslinking sites upon polymerization.

As used herein, the term “group” may refer to a functional group of a chemical compound. Groups of the present compounds refer to an atom or a collection of atoms that are a part of the compound. Groups of the present disclosure may be attached to other atoms of the compound via one or more covalent bonds. Groups may also be characterized with respect to their valence state. The present disclosure includes groups characterized as monovalent, divalent, trivalent, etc. valence states.

As used herein, a wavy line in a chemical structure can be used to indicate a bond to the rest of the molecule. For example,

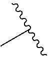

in, e.g.,

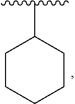 [SMILES: *C1CCCCC1]

can be used to indicate that the given moiety, the cyclohexyl moiety in this example, is attached to a molecule via the bond that is “capped” with the wavy line.

As used herein, a “linker” refers to a contiguous chain of at least one atom, such as carbon, oxygen, nitrogen, sulfur, phosphorous, and combinations thereof, which connects a portion of a molecule to another portion of the same molecule or to a different molecule, moiety or solid support (e.g., microparticle). Linkers may connect the molecule via a covalent bond or other means, such as ionic or hydrogen bond interactions. In some embodiments, the linker is a heteroatomic linker (e.g., comprising 1-10 Si, N, O, P, or S atoms), a heteroalkylene (e.g., comprising 1-10 Si, N, O, P, or S atoms and an alkylene chain) or an alkylene linker (e.g., comprising 1-12 carbon atoms). In some embodiments, the linker may contain an ether (—O—), ester (—OC(═O)—), or carbonate (—OC(═O)O—) linkage.

“Hydroxy” or “hydroxyl” refers to the —OH group.

“Aromatic” or “aromatic group” as used herein refers to a major group of unsaturated cyclic hydrocarbons containing one or more rings. An aromatic group may contain carbon (C), nitrogen (N), oxygen (O), sulfur(S), boron (B), or any combination thereof. At least some carbon is included. Aromatic includes both aryl and heteroaryl rings.

“Aliphatic” or “aliphatic group” as used herein means a straight-chain or branched C₁₋₁₂ hydrocarbon chain that is completely saturated or that contains one or more units of unsaturation, or a monocyclic C₃₋₈ hydrocarbon or bicyclic C₈₋₁₂ hydrocarbon that is completely saturated or that contains one or more units of unsaturation, but which is not aromatic (also referred to herein as “cycloalkyl”), that has a single point of attachment to the rest of the molecule where in any individual ring in said bicyclic ring system has 3-7 members. For example, suitable aliphatic groups include, but are not limited to, linear or branched alkyl, alkenyl, alkynyl groups and hybrids thereof such as (cycloalkyl)alkyl, (cycloalkenyl)alkyl or (cycloalkyl)alkenyl.

“Alkyl” or “alkyl group” refers to a straight or branched hydrocarbon chain group consisting solely of carbon and hydrogen atoms, containing no unsaturation, having from one to twelve carbon atoms (C₁-C₁₂ alkyl), one to eight carbon atoms (C₁-C₈ alkyl) or one to six carbon atoms (C₁-C₆ alkyl), and which is attached to the rest of the molecule by a single bond, e.g., methyl, ethyl, n-propyl, 1-methylethyl (iso-propyl), n-butyl, n-pentyl, 1,1-dimethylethyl (t-butyl), 3-methylhexyl, 2-methylhexyl, and the like. Unless stated otherwise specifically in the specification, alkyl groups are optionally substituted.

“Alkylene” or “alkylene group” refers to a straight or branched divalent hydrocarbon chain linking the rest of the molecule to a radical group, consisting solely of carbon and hydrogen, containing no unsaturation, and having from one to twelve carbon atoms, e.g., methylene, ethylene, propylene, n-butylene, and the like. The alkylene chain is attached to the rest of the molecule through a single bond and to the radical group through a single bond. The points of attachment of the alkylene chain to the rest of the molecule and to the radical group can be through one carbon or any two carbons within the chain. Unless stated otherwise specifically in the specification, alkylene is optionally substituted.

“Aryl” or “alkyl group” refers to a ring system comprising at least one carbocyclic aromatic ring. In some embodiments, an aryl comprises from 6 to 18 carbon atoms. The aryl ring may be a monocyclic, bicyclic, tricyclic or tetracyclic ring system, which may include fused or bridged ring systems. Aryls include, but are not limited to, aryls derived from aceanthrylene, acenaphthylene, acephenanthrylene, anthracene, azulene, benzene, chrysene, fluoranthene, fluorene, as-indacene, s-indacene, indane, indene, naphthalene, phenalene, phenanthrene, pleiadene, pyrene, and triphenylene. Unless stated otherwise specifically in the specification, an aryl group is optionally substituted.

“Arylene” or “arylene group” refers to a divalent group derived from an aryl group as defined herein. In some embodiments, an arylene is a divalent group derived from an aryl group by removal of hydrogen atoms from two intra-ring carbon atoms of an aromatic ring of the aryl group. Arylene groups in some compounds function as attaching and/or spacer groups. Arylene groups in some compounds function as chromophore, fluorophore, aromatic antenna, dye and/or imaging groups. Compounds of the present disclosure include substituted and/or unsubstituted C₅-C₃₀ arylene, C₅-C₂₀ arylene, and C₅-C₁₀ arylene groups “Cycloalkyl” or “cycloalkyl group” refers to a stable non-aromatic monocyclic or polycyclic carbocyclic ring, which may include fused or bridged ring systems, having from three to fifteen carbon atoms, preferably having from three to ten carbon atoms, and which is saturated or unsaturated and attached to the rest of the molecule by a single bond. Monocyclic cycloalkyls include, for example, cyclopropyl, cyclobutyl, cyclopentyl, cyclohexyl, cycloheptly, and cyclooctyl. Polycyclic cycloalkyls include, for example, adamantyl, norbornyl, decalinyl, 7,7-dimethyl-bicyclo-[2.2.1]heptanyl, and the like. Unless stated otherwise specifically in the specification, a cycloalkyl group is optionally substituted.

“Cycloalkylene” or “cycloalkylene group” refers divalent group derived from a cycloalkyl group as defined herein. Cycloalkyl groups in some compounds function as attaching and/or spacer groups. Compounds of the present disclosure may have substituted and/or unsubstituted C₃-C₂₀ cycloalkylene, C₃-C₁₀ cycloalkylene and C₃-C₅ cycloalkylene groups.

“Heteroalkyl” refers to an alkyl group, as defined above, comprising at least one heteroatom (e.g., N, O, P or S) within the alkyl group or at a terminus of the alkyl group. In some embodiments, the heteroatom is within the alkyl group (i.e., the heteroalkyl comprises at least one carbon-[heteroatom]x-carbon bond, where x is 1, 2 or 3). In other embodiments, the heteroatom is at a terminus of the alkyl group and thus serves to join the alkyl group to the remainder of the molecule (e.g., M1-H-A), where M1 is a portion of the molecule, H is a heteroatom and A is an alkyl group). Unless stated otherwise specifically in the specification, a heteroalkyl group is optionally substituted. Exemplary heteroalkyl groups include ethylene oxide (e.g., polyethylene oxide), optionally including phosphorous-oxygen bonds, such as phosphodiester bonds.

“Heteroalkylene” or “heteroalkylene group” refers to an alkylene group, as defined above, comprising at least one heteroatom (e.g., N, O, P or S) within the alkylene chain or at a terminus of the alkylene chain. In some embodiments, the heteroatom is within the alkylene chain (i.e., the heteroalkylene comprises at least one carbon-[heteroatom]-carbon bond, where x is 1, 2 or 3). In other embodiments, the heteroatom is at a terminus of the alkylene and thus serves to join the alkylene to the remainder of the molecule (e.g., M1-H-A-M2, where M1 and M2 are portions of the molecule, H is a heteroatom and A is an alkylene). Unless stated otherwise specifically in the specification, a heteroalkylene group is optionally substituted.

“Heteroatomic” in reference to a “heteroatomic linker” refers to a linker group consisting of one or more heteroatoms. Exemplary heteroatomic linkers include single atoms selected from the group consisting of O, N, P and S, and multiple heteroatoms for example a linker having the formula —P(O—)(═O)O— or —OP(O—)(═O)O— and multimers and combinations thereof.

“Heteroaryl” or “heteroaryl group” refers to a 5- to 30-membered ring system comprising one to thirteen carbon atoms, one to six heteroatoms selected from the group consisting of nitrogen, oxygen and sulfur, and at least one aromatic ring. For purposes of certain embodiments of this disclosure, the heteroaryl radical may be a monocyclic, bicyclic, tricyclic or tetracyclic ring system, which may include fused or bridged ring systems; and the nitrogen, carbon or sulfur atoms in the heteroaryl radical may be optionally oxidized; the nitrogen atom may be optionally quaternized. Examples include, but are not limited to, azepinyl, acridinyl, benzimidazolyl, benzthiazolyl, benzindolyl, benzodioxolyl, benzofuranyl, benzooxazolyl, benzothiazolyl, benzothiadiazolyl, benzo[b][1,4]dioxepinyl, 1,4-benzodioxanyl, benzonaphthofuranyl, benzoxazolyl, benzodioxolyl, benzodioxinyl, benzopyranyl, benzopyranonyl, benzofuranyl, benzofuranonyl, benzothienyl(benzothiophenyl), benzotriazolyl, benzo[4,6]imidazo[1,2-a]pyridinyl, benzoxazolinonyl, benzimidazolthionyl, carbazolyl, cinnolinyl, dibenzofuranyl, dibenzothiophenyl, furanyl, furanonyl, isothiazolyl, imidazolyl, indazolyl, indolyl, indazolyl, isoindolyl, indolinyl, isoindolinyl, isoquinolyl, indolizinyl, isoxazolyl, naphthyridinyl, oxadiazolyl, 2-oxoazepinyl, oxazolyl, oxiranyl, 1-oxidopyridinyl, 1-oxidopyrimidinyl, 1-oxidopyrazinyl, 1-oxidopyridazinyl, 1-phenyl-1H-pyrrolyl, phenazinyl, phenothiazinyl, phenoxazinyl, phthalazinyl, pteridinyl, pteridinonyl, purinyl, pyrrolyl, pyrazolyl, pyridinyl, pyridinonyl, pyrazinyl, pyrimidinyl, pryrimidinonyl, pyridazinyl, pyrrolyl, pyrido[2,3-d]pyrimidinonyl, quinazolinyl, quinazolinonyl, quinoxalinyl, quinoxalinonyl, quinolinyl, isoquinolinyl, tetrahydroquinolinyl, thiazolyl, thiadiazolyl, thieno[3,2-d]pyrimidin-4-onyl, thieno[2,3-d]pyrimidin-4-onyl, triazolyl, tetrazolyl, triazinyl, and thiophenyl (i.e., thienyl). Unless stated otherwise specifically in the specification, a heteroaryl group is optionally substituted.

“Heteroarylene” or “heteroarylene group” refers to a divalent group derived from a heteroaryl group as defined herein. In some embodiments, a heteroarylene is a divalent group derived from a heteroaryl group by removal of hydrogen atoms from two intra-ring carbon atoms or intra-ring nitrogen atoms of a heteroaromatic or aromatic ring of the heteroaryl group. Heteroarylene groups in some compounds function as attaching and/or spacer groups. Heteroarylene groups in some compounds function as chromophore, aromatic antenna, fluorophore, dye and/or imaging groups. Compounds of the present disclosure include substituted and/or unsubstituted C₅-C₃₀ heteroarylene, C₅-C₂₀ heteroarylene and C₅-C₁₀ heteroarylene groups.

“Heterocyclic” or “heterocyclic group” refers to a stable 3- to 18-membered aromatic or non-aromatic ring comprising one to twelve carbon atoms and from one to six heteroatoms selected from the group consisting of nitrogen, oxygen and sulfur. Unless stated otherwise specifically in the specification, the heterocyclic ring may be a monocyclic, bicyclic, tricyclic or tetracyclic ring system, which may include fused or bridged ring systems; and the nitrogen, carbon or sulfur atoms in the heterocyclic ring may be optionally oxidized; the nitrogen atom may be optionally quaternized; and the heterocyclic ring may be partially or fully saturated. Examples of aromatic heterocyclic rings are listed below in the definition of heteroaryls (i.e., heteroaryl being a subset of heterocyclic). Examples of non-aromatic heterocyclic rings include, but are not limited to, dioxolanyl, thienyl[1,3]dithianyl, decahydroisoquinolyl, imidazolinyl, imidazolidinyl, isothiazolidinyl, isoxazolidinyl, morpholinyl, octahydroindolyl, octahydroisoindolyl, 2-oxopiperazinyl, 2-oxopiperidinyl, 2-oxopyrrolidinyl, oxazolidinyl, piperidinyl, piperazinyl, 4-piperidonyl, pyrrolidinyl, pyrazolidinyl, pyrazolopyrimidinyl, quinuclidinyl, thiazolidinyl, tetrahydrofuryl, trioxanyl, trithianyl, triazinanyl, tetrahydropyranyl, thiomorpholinyl, thiamorpholinyl, 1-oxo-thiomorpholinyl, and 1,1-dioxo-thiomorpholinyl. Unless stated otherwise specifically in the specification, a heterocyclic group is optionally substituted.

The term “substituted” used herein means any of the above groups wherein at least one hydrogen atom (e.g., 1, 2, 3 or all hydrogen atoms) is replaced by a bond to a non-hydrogen atoms such as, but not limited to: a halogen atom such as F, Cl, Br, and I; an oxygen atom in groups such as hydroxyl groups, alkoxy groups, and ester groups; a sulfur atom in groups such as thiol groups, thioalkyl groups, sulfone groups, sulfonyl groups, and sulfoxide groups; a nitrogen atom in groups such as amines, amides, alkylamines, dialkylamines, arylamines, alkylarylamines, diarylamines, N-oxides, imides, and enamines; a silicon atom in groups such as trialkylsilyl groups, dialkylarylsilyl groups, alkyldiarylsilyl groups, and triarylsilyl groups; and other heteroatoms in various other groups. “Substituted” also means any of the above groups in which one or more hydrogen atoms are replaced by a higher-order bond (e.g., a double- or triple-bond) to a heteroatom such as oxygen in oxo, carbonyl, carboxyl, and ester groups; and nitrogen in groups such as imines, oximes, hydrazones, and nitriles. For example, “substituted” includes any of the above groups in which one or more hydrogen atoms are replaced with —NR_{g}Rₕ, —NR_{g}C(═O) Rₕ, —NR_{g}C(═O) NR_{g}Rₕ, —NR_{g}C(═O)ORₕ, —NR_{g}SO₂Rₕ, —OC(═O) NR_{g}Rₕ, —OR_{g}, —SR_{g}, —SOR_{g}, —SO₂R_{g}, —OSO₂R_{g}, —SO₂OR_{g}, ═NSO₂R_{g}, and —SO₂NR_{g}Rₕ. “Substituted” also means any of the above groups in which one or more hydrogen atoms are replaced with —C(═O)R_{g}, —C(═O) OR_{g}, —C(═O)NR_{g}Rₙ, —CH₂SO₂R_{g}, and —CH₂SO₂NR_{g}Rₕ. In the foregoing, R_{g} and Rₙ are the same or different and independently hydrogen, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl and/or heteroarylalkyl. “Substituted” further means any of the above groups in which one or more hydrogen atoms are replaced by a bond to an amino, cyano, hydroxyl, imino, nitro, oxo, thioxo, halo, alkyl, alkoxy, alkylamino, thioalkyl, aryl, aralkyl, cycloalkyl, cycloalkylalkyl, haloalkyl, heterocyclyl, N-heterocyclyl, heterocyclylalkyl, heteroaryl, N-heteroaryl and/or heteroarylalkyl group. In addition, each of the foregoing substituents may also be optionally substituted with one or more of the above substituents.

IC fabrication uses one or more photolithography processes to transfer geometric patterns to a film or substrate. Geometric shapes and patterns on a semiconductor make up the complex structures that allow the dopants, electrical properties and wires to complete a circuit and fulfill a technological purpose. In a photolithography process, a photoresist is applied as a thin film to a substrate, and subsequently exposed to one or more types of radiation or light through a photomask. The photomask contains clear and opaque features that form a pattern which is to be created in the photoresist layer. After the photoresist layer is exposed to a radiation, it is developed in a developer (a chemical solution). The developer removes portions of the photoresist layer, thereby forming a photoresist pattern which may include line patterns and/or trench patterns. The photoresist pattern is then used as an etch mask in subsequent etching processes, transferring the pattern to underlying layers. There are generally two types of processes for developing exposed photoresist layer: a positive tone development (PTD) process and a negative tone development (NTD) process. The PTD process uses a positive tone developer that selectively dissolves and removes the exposed portions of the photoresist layer. The NTD process uses a negative tone developer that selectively dissolves and removes the unexposed portions of the photoresist layer. Quality of the photoresist pattern directly impacts a quality of the IC device. As IC technologies continually progress towards smaller technology nodes (for example, down to 14 nanometers, 10 nanometers, and below), resolution, roughness (for example, line edge roughness (LER) and/or line width roughness (LWR)), and/or contrast of the photoresist pattern is highly related.

Advanced lithography materials, such as chemically amplified resist (CAR) materials, have been introduced to improve sensitivity of the photoresist layer to the radiation, thereby maximizing utilization of the radiation. A photoresist layer formed from a CAR material includes a polymer that is resistant to an IC process (such as an etching process) and an acid generator (such as a photoacid generator (PAG)). The PAG generates acid upon exposure to radiation, which functions as a catalyst for causing chemical reactions that increase (or decrease) solubility of exposed portions of the resist layer. For example, in some embodiments, acid generated from the PAG catalysts cleavage of acid labile groups (ALGs) bonded to the polymer, thereby changing solubility of exposed portions of the photoresist layer.—However, the CAR reaction may lead to certain undesirable side effects. For example, photolithography processes usually include a post-exposure bake (PEB) step. The cleaved ALG is volatile and evaporates in the PEB process, causing film shrinkage in the exposed areas. This leads to poor pattern profile and/or poor resolution.

The present disclosure provides photoresist materials with good developer solubility, high resolution and etch resistance but reduced volume shrinkage. In embodiments of the present disclosure, photoresist materials having an ALG linked to a polymer backbone via an etch resistance promoting group that has a size bigger than or comparable to that of the ALG are provided. After cleavage of the ALG, the etch resistance promoting group remains attached to the polymer backbone, the volume shrinkage of the photoresist layer due to ALG evaporation (i.e., outgassing) is thus reduced or eliminated. Consequently, good pattern profiles with reduced LER and LWR as well as high resolution and etch resistance are achieved.

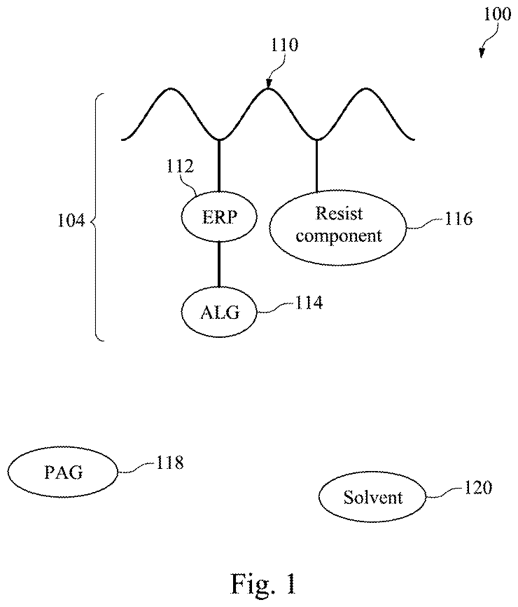

FIG. 1 illustrates a photoresist composition 100 that can be used for forming a photoresist layer, in accordance some embodiments of the present disclosure. For purposes of the following discussion, the photoresist composition 100 includes a negative tone photoresist resist material used to form a negative tone photoresist resist layer, where portions of the photoresist layer exposed to radiation become insoluble to a developer and unexposed portions of the photoresist layer remain soluble to the developer. Alternatively, the present disclosure contemplates embodiments where photoresist composition 100 includes a positive tone resist material used to form a positive tone photoresist layer, where portions of photoresist layer exposed to radiation become soluble to a developer and unexposed portions of photoresist layer remain insoluble to the developer. In some embodiments, the photoresist composition 100 is sensitive to radiation having a wavelength less than about 250 nm. FIG. 1 has been simplified for the sake of clarity to better understand the inventive concepts of the present disclosure. Additional features can be added in the photoresist composition 100, and some of the features described below can be replaced, modified, or eliminated in other embodiments of the photoresist composition 100.

In some embodiments, the photoresist composition 100 includes a photosensitive polymer 104 having a resistance to an IC process used during IC fabrication. For example, the polymer 104 has an etch-resistance to an etching process and/or an implant-resistance to an implantation process. The polymer 104 includes a polymer backbone 110. In some embodiments, the polymer backbone 110 is a hydrocarbon backbone including a backbone of a poly(norbornene)-co-malaic anhydride (COMA) polymer, a poly(4-hydroxystyrene) (PHS) polymer, a phenol-formaldehyde (hakelite) polymer, a polyethylene (PE) polymer, a polypropylene (PP) polymer, a polycarbonate polymer, a polyester polymer, or an acrylate-based polymer, such as a poly(methyl methacrylate) (PMMA) polymer.

The polymer 104 has a plurality of functional groups chemically bonded to the polymer backbone 110, such as an etch resistance promoting (ERP) group 112, and an acid labile group (ALG) 114. The etch resistance promoting group 112 is adapted to increase the etch resistance of the polymer 104 to a wet etch or dry etch process. The ALG 114 is chemically bonded to the etch resistance promoting group 112 and is adapted to change solubility of the polymer 104 in response to acid. For example, the ALG114 is cleaved from side chain of the polymer 104 upon exposure to acid, thereby changing a solubility and/or polarity of exposed portions of the photoresist layer. In some embodiments, the ALG 114 may have a 1D, 2D or 3D structure to control the activation energy. The activation energy is the minimum energy to start a deprotection reaction of ALG 114.

In some embodiments, a resist component 116 may be bonded to the polymer backbone 110. The resist component 116 is configured to interact with other components of the photoresist composition 100. In some embodiments, the resist component 116 may include a thermal acid generator (TAG), a quencher (base), a chromophore, a crosslinker, a surfactant, and/or other suitable components depending on requirements of photoresist composition 100. The present disclosure also contemplates embodiments where resist component 116 interacts with components of photoresist composition 100, yet is not chemically bonded (or linked) to the polymer backbone 110 as depicted in FIG. 1.

In some embodiments, the polymer 104 includes a monomeric unit having an ALG bonded to a polymer backbone via an etch resistant promoting group. In some embodiments, the polymer 104 comprising a monomeric unit having the following structure (I):

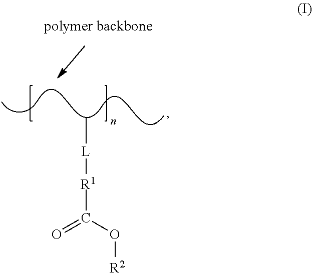

wherein:
L is a direct bond, an alkylene, heteroalkylene, cycloalkylene ether, arylene ether, —CO—, —C(O)O—, —CONR^{a}—, —O—, —S—, —S(O)—, —SO₂— or —P(O)OH— linker;
R¹ is an etch resistance promoting group;
R² is an acid labile group;
R^{a} is H or an alkyl group; and
n is an integer of 1 to 500.

In some embodiments, L is —(CO)O—.

In some embodiments, R¹ is an alkylene, heteroalkylene, cycloalkylene, cycloheteroalkylene or arylene group.

In some embodiments, R¹ is C₁₋₁₂ alkylene.

In some embodiments, R¹ is cyclo(C₃₋₁₂)alkylene. In some embodiments, the cyclo(C₃₋₁₂)alkylene is bicyclic alkylene.

In some embodiments, R¹ is cyclo(C₃₋₁₂) heteroalkylene. In some embodiments, the cyclo(C₃₋₁₂) heteroalkylene is bicyclic heteroalkylene.

In some embodiments, R¹ is phenylene.

In some embodiments, R¹ has one of the following structures:

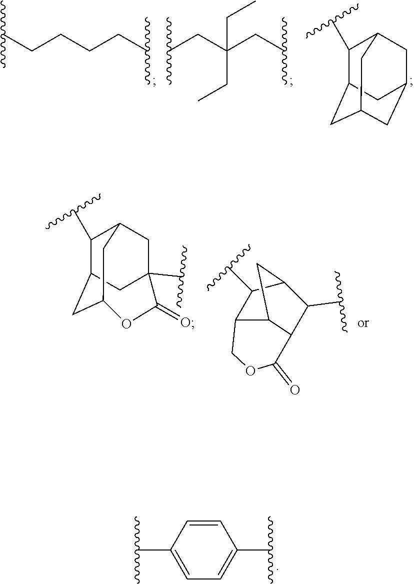

In some embodiments, R² is an alkyl, heteroalkyl, cycloalkyl or cycloheteroalkyl group.

In some embodiments, R² is C₁₋₁₂ alkyl.

In some embodiments, R² is cyclo(C₃₋₁₂)alkyl. In some embodiments, the cyclo(C₃₋₁₂)alkyl is bicyclic alkyl.

In some embodiments, R² is n-butyl, t-butyl, methyl adamantyl, methyl cyclopentyl, methyl cyclohexyl, ethyl cyclopentyl, ethyl cyclohexyl, isopropyl, cyclopentyl, isopropyl cyclohexyl, tert-butoxycarbonyl, iso-norbomyl, 2-methyl-2-adamantyl, 2-ethyl-2-adamantyl, 3-methyl tetrahydrofuran, 2-methyl tetrahydrofuran, lactone, or 2-methyl tetrahydropyran (THP).

In some embodiments, R² has one of the following structures:

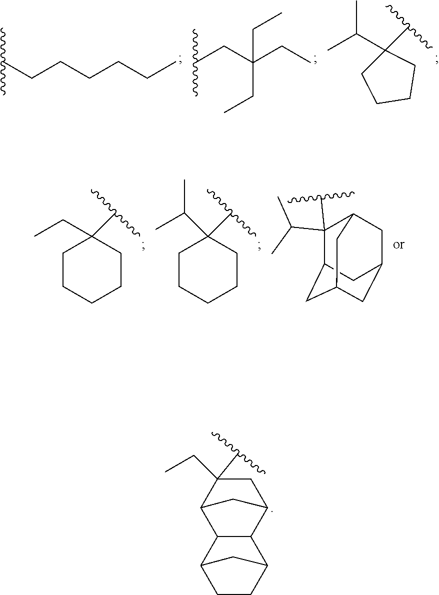

In some embodiments, R^{a} is H or —CH₃.

In some embodiments, the monomeric unit (I) has the following structure (Ia):

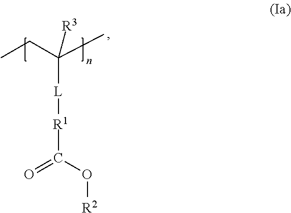

wherein:
L, R¹, R², and n are as defined above; and
R³ is H or alkyl.

In some embodiments, R³ is-CH₃.

In some embodiments, the monomeric unit (Ia) has the following structure:

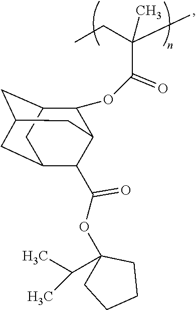

wherein n is 1 to 500.

In some embodiments, the polymer 104 comprises, in a polymeric form, a monomer having the following structure (II):

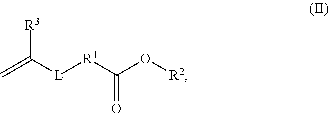

wherein:
L is a direct bond, or an alkylene, heteroalkylene, cycloalkylene ether, arylene ether, —CO—, —C(O)O—, —CONR^{a}—, —O—, —S—, —S(O)—, —SO₂— or —P(O)OH— linker;
R¹ is an alkylene, heteroalkylene, cycloalkylene, cycloheteroalkylene or arylene group;
R² is an alkyl, heteroalkyl, cycloalkyl or cycloheteroalkyl group;
R³ is H or an alkyl group; and
R^{a} is H or an alkyl group.

In some embodiments, L is —(CO)O—, and the monomer (II) has the following

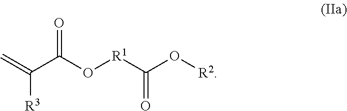

In some embodiments, the monomer has the following structure:

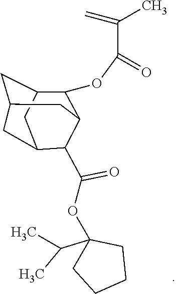 [SMILES: C=C(C)C(=O)OC1C2CC3CC(C2)C(C(=O)OC2(C(C)C)CCCC2)C1C3]

The photoresist composition 100 further includes an acid generator, such as a photoacid generator (PAG) 118, which generates acid upon absorbing radiation. The PAG 118 thus catalyzes cleavage of ALG 114 from side chain of the polymer 104 when exposed to radiation, deprotecting ALG 114 in exposed portions of the photoresist layer and changing characteristics (for example, polarity and/or solubility) of exposed portions of the photoresist layer. In some embodiments, the PAG 118 includes a fluorine-containing functional group, such as perfluorosulfonate, diphenyliodonium trifluoromethane sulfonate, diphenyliodonium nonafluorobutane sulfonate, triphenylsulfonium trifluromethane sulfonate, triphenylsulfonium nonafluorobutane sulfonate, triphenylsulfonium bis(perfluoromethanesulfonyl)imide, fluorine-containing functional group, or combinations thereof. In some embodiments, the PAG 118 includes a phenyl ring based functional group, a heterocyclic ring based functional group, other suitable functional group, or combinations thereof. In embodiments where the photoresist composition 100 includes a quencher, the quencher neutralizes acid, such that the quencher inhibits acid generated by the PAG 118 from reacting with ALG 114. In some embodiments, the quencher is a photo-decomposable base (PDB) component.

In some embodiments, the PAG 118 may include a combination of a cation and an anion. Examples of photoacid generators according to embodiments of the disclosure include a-(trifluoromethylsulfonyloxy)-bicyclo[2.2.1]hept-5-ene-2,3-dicarb-o-ximide (MDT), N-hydroxy-naphthalimide (DDSN), benzoin tosylate, t-butylphenyl-a-(p-toluenesulfonyloxy)acetate and t-butyl-a-(p-toluenesulfonyloxy)acetate, triarylsulfonium and diaryliodonium hexafluoroantimonates, hexafluoroarsenates, trifluoromethanesulfonates, iodonium perfluorooctanesulfonate, N-camphorsulfonyloxynaphthalimide, N-pentafluorophenylsulfonyloxynaphthalimide, ionic iodonium sulfonates such as diaryl iodonium (alkyl or aryl) sulfonate and bis-(di-t-butylphenyl) iodonium camphanylsulfonate, perfluoroalkanesulfonates such as perfluoropentanesulfonate, perfluorooctanesulfonate, perfluoromethanesulfonate, aryl (e.g., phenyl or benzyl)triflates such as triphenylsulfonium triflate or bis(t-butylphenyl) iodonium triflate; pyrogallol derivatives (e.g., trimesylate of pyrogallol), trifluoromethanesulfonate esters of hydroxyimides, a,a′-bis-sulfonyl-diazomethanes, sulfonate esters of nitro-substituted benzyl alcohols, naphthoquinone-4-diazides, alkyl disulfones, or the like.

In some embodiments, the cation is selected from the group consisting of:

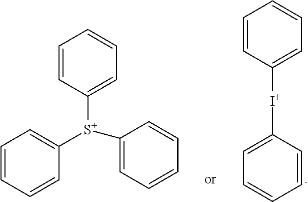 [SMILES: c1ccc([S+](c2ccccc2)c2ccccc2)cc1 ; c1ccc([I+]c2ccccc2)cc1]

In some embodiments, the anion is selected from the group consisting of:

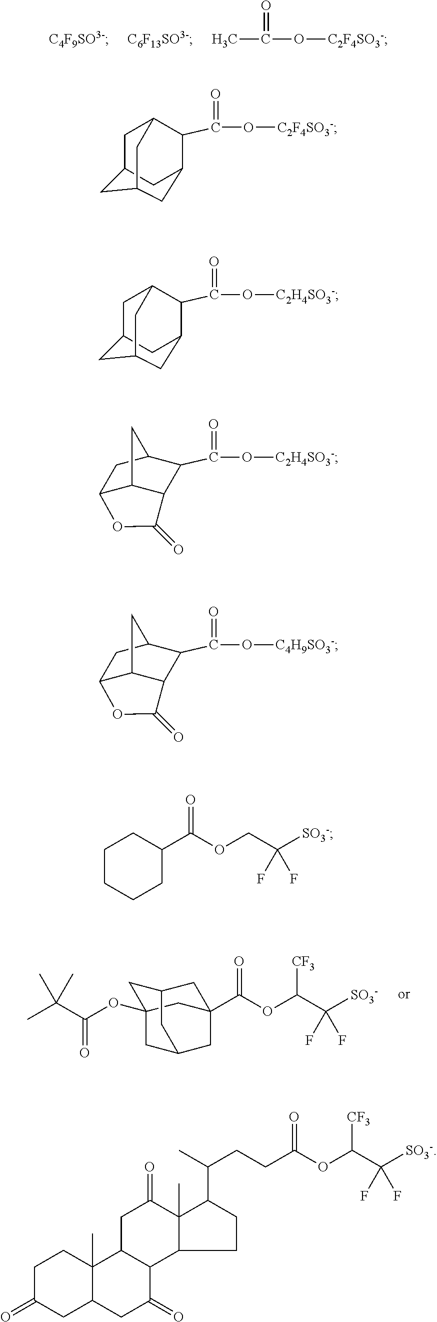

In some embodiments, the photoresist composition 100 also comprises a solvent 120. In some embodiments, the solvent 120 is an aqueous solvent. In some embodiments, the solvent 330 is an organic-based solvent, such as propylene glycol methyl ether acetate (PGMEA), propylene glycol monomethyl ether (PGME), 1-ethoxy-2-propanol (PGEE), Y-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), 2-heptanone (MAK), other suitable organic-based solvent, or combinations thereof.

When forming photoresist composition 100, polymer 104, PAG 118 and any resist components are mixed in the solvent 120, thereby forming a resist solution for photolithography.

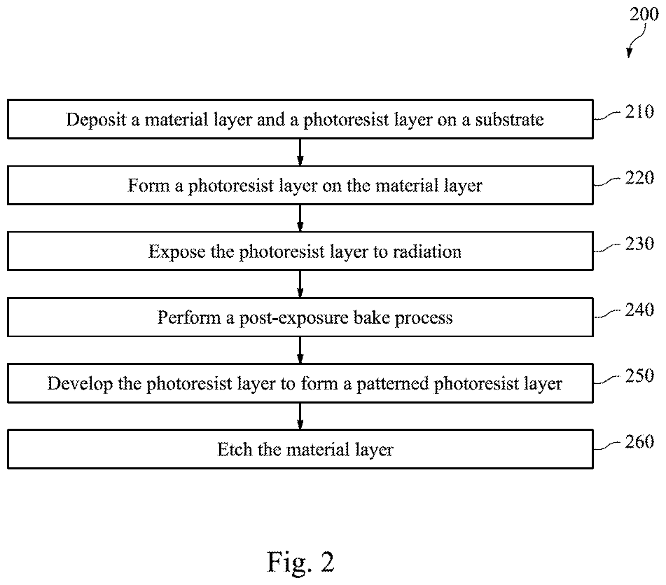

FIG. 2 is a flowchart illustrating a method 200 of fabricating a semiconductor device 300, in accordance with some embodiments of the present disclosure. The method 200 may be implemented, in whole or in part, by a system employing advanced lithography processes, such as DUV lithography, EUV lithography, e-beam lithography, x-ray lithography, and/or other lithography to enhance lithography resolution. At block 210, a material layer is formed over a substrate. At block 220, a photoresist layer is formed over the material layer. At block 230, the photoresist layer is exposed, for example, to patterned radiation. At block 240, the photoresist layer is baked, for example, by a post-exposure bake process. At block 250, the photoresist layer is developed, thereby forming a patterned photoresist layer. At block 260, the material layer is etched using the patterned photoresist layer as a mask. Additional steps can be provided before, during, and after method 200, and some of the steps described can be moved, replaced, or eliminated for additional embodiments of method 200.

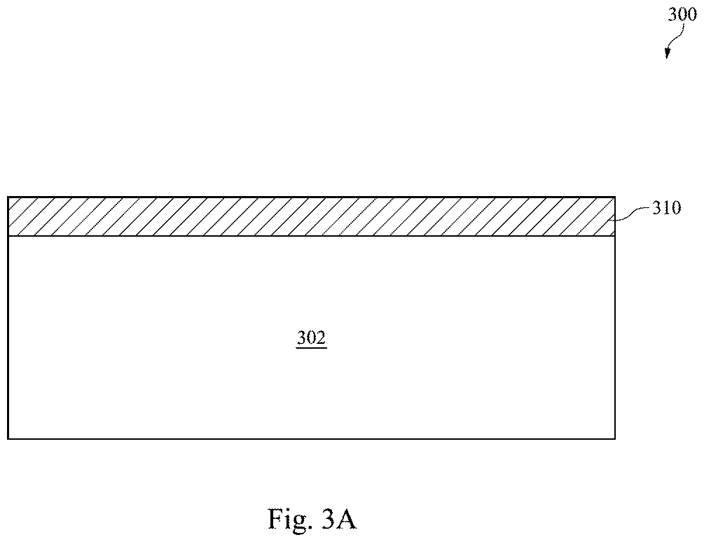

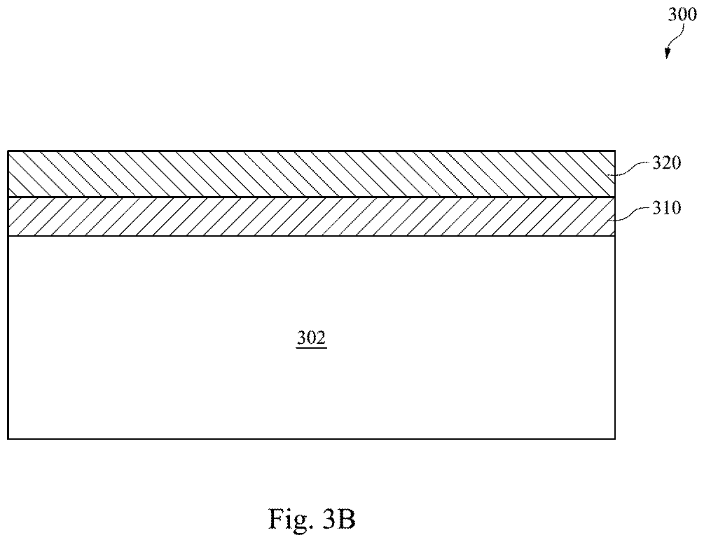

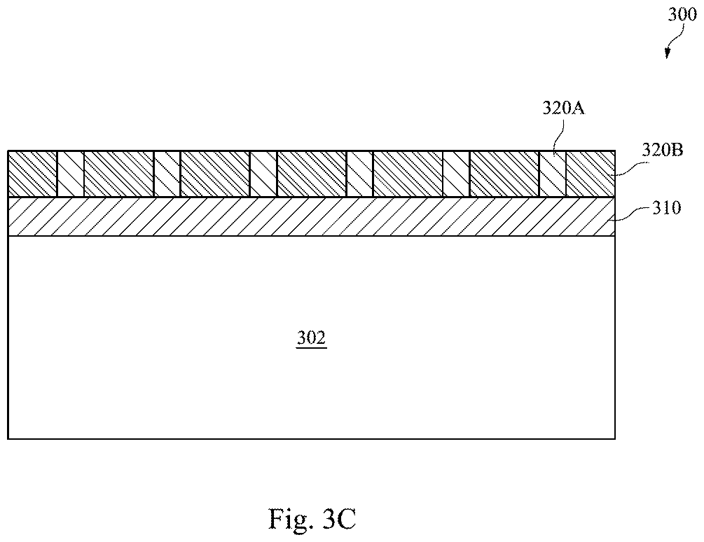

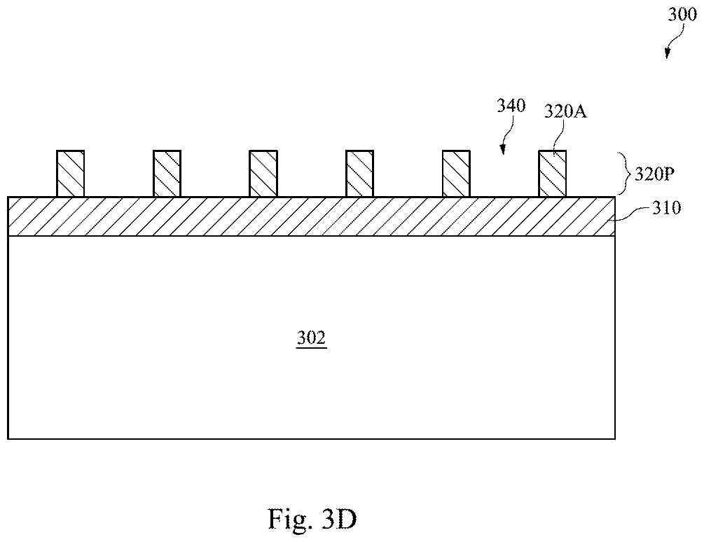

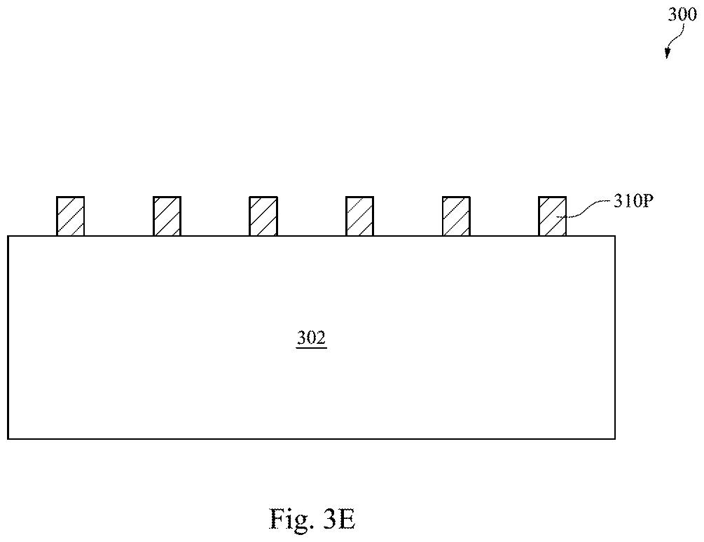

FIGS. 3A-3E are fragmentary cross-sectional views of a semiconductor device 300 at various fabrication stages of the method 200, in accordance with some embodiments of the present disclosure. The semiconductor device 300 may be an intermediate structure during the fabrication of an IC, or a portion thereof. The IC may include logic circuits, memory structures, passive components (such as resistors, capacitors, and inductors), and active components such as diodes, field-effect transistors (FETs), metal-oxide semiconductor field effect transistors (MOSFETs), complementary metal-oxide semiconductor (CMOS) transistors, bipolar transistors, high voltage transistors, high frequency transistors, fin-like FETs (FinFETs), other three-dimensional (3D) FETs, and combinations thereof. The semiconductor device 300 may include a plurality of semiconductor devices (e.g., transistors), which may be interconnected.

Referring to FIG. 3A, the semiconductor device 300 includes a substrate 302. In some embodiments, the substrate 302 may be a bulk semiconductor substrate including one or more semiconductor materials. In some embodiments, the substrate 302 may include silicon, silicon germanium, carbon doped silicon (Si: C), silicon germanium carbide, or other suitable semiconductor materials. In some embodiments, the substrate 302 is composed entirely of silicon.

In some embodiments, the substrate 302 may include one or more epitaxial layers formed on a top surface of a bulk semiconductor substrate. In some embodiments, the one or more epitaxial layers introduce strains in the substrate 302 for performance enhancement. For example, the epitaxial layer includes a semiconductor material different from that of the bulk semiconductor substrate, such as a layer of silicon germanium overlying bulk silicon or a layer of silicon overlying bulk silicon germanium. In some embodiments, the epitaxial layer(s) incorporated in the substrate 302 are formed by selective epitaxial growth, such as, for example, metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), or combinations thereof.

In some embodiments, the substrate 302 may be a semiconductor-on-insulator (SOI) substrate. In some embodiments, the SOI substrate includes a semiconductor layer, such as a silicon layer formed on an insulator layer. In some embodiments, the insulator layer is a buried oxide (BOX) layer including silicon oxide or silicon germanium oxide. The insulator layer is provided on a handle substrate such as, for example, a silicon substrate. In some embodiments, the SOI substrate is formed using separation by implanted oxygen (SIMOX) or other suitable technique, such as wafer bonding and grinding.

In some embodiments, the substrate 302 may also include a dielectric substrate such as silicon oxide, silicon nitride, silicon oxynitride, a low-k dielectric, silicon carbide, and/or other suitable layers.

In some embodiments, the substrate 302 may also include various p-type doped regions and/or n-type doped regions, implemented by a process such as ion implantation and/or diffusion. Those doped regions include n-well, p-well, lightly doped region (LDD) and various channel doping profiles configured to form various IC devices, such as a COMOS transistor, imaging sensor, and/or light emitting diode (LED). The substrate 302 may further include other functional features such as a resistor and/or a capacitor formed in and/or on the substrate 302.

In some embodiments, the substrate 302 may also include various isolation features. The isolation features separate various device regions in the substrate 302. The isolation features include different structures formed by using different processing technologies. For example, the isolation features may include shallow trench isolation (STI) features. The formation of an STI may include etching a trench in the substrate 302 and filling in the trench with insulator materials such as silicon oxide, silicon nitride, and/or silicon oxynitride. The filled trench may have a multi-layer structure such as a thermal oxide liner layer with silicon nitride filling the trench. A chemical mechanical polishing (CMP) may be performed to polish back excessive insulator materials and planarize the top surface of the isolation features.

In some embodiments, the substrate 302 may also include gate stacks formed by dielectric layers and electrode layers. The dielectric layers may include an interfacial layer and a high-k dielectric layer deposited by suitable techniques, such as chemical vapor deposition (CVD), atomic layer deposition (ALD), physical vapor deposition (PVD), thermal oxidation, combinations thereof, and/or other suitable techniques. The interfacial layer may include silicon dioxide and the high-k dielectric layer may include LaO, AlO, ZrO, TiO, Ta₂O₅, Y₂O₃, SrTiO₃, BaTiO₃, BaZrO, HfZrO, HfLaO, HfSiO, LaSiO, AlSiO, HfTaO, HfTiO, (Ba,Sr) TiO₃ (BST), Al₂O₃, Si₃N₄, SiON, and/or other suitable materials. The electrode layer may include a single layer or alternatively a multi-layer structure, such as various combinations of a metal layer with a work function to enhance the device performance (work function metal layer), liner layer, wetting layer, adhesion layer and a conductive layer of metal, metal alloy or metal silicide. The electrode layer may include Ti, Ag, Al, TiAIN, TaC, TaCN, TaSiN, Mn, Zr, TiN, TaN, Ru, Mo, Al, WN, Cu, W, any suitable materials, and/or a combination thereof.

In some embodiments, the substrate 302 may also include a plurality of inter-level dielectric (ILD) layers and conductive features integrated to form an interconnect structure configured to couple the various p-type and n-type doped regions and the other functional features (such as gate electrodes), resulting in a functional integrated circuit. In one example, the substrate 302 may include a portion of the interconnect structure and the interconnect structure may include a multi-layer interconnect (MLI) structure and an ILD layer integrated with a MLI structure, providing an electrical routing to couple various devices in the substrate 302 to the input/output power and signals. The interconnect structure includes various metal lines, contacts and via features (or via plugs). The metal lines provide horizontal electrical routing. The contacts provide vertical connection between silicon substrate and metal lines while via features provide vertical connection between metal lines in different metal layers.

A material layer 310 is deposited on a substrate 302. The material layer 310 is a layer to be processed by the method 200, such as to be pattered or to be implanted. In some embodiments, the material layer 310 is a hard mask layer to be patterned. In some embodiments, the material layer 310 includes a dielectric material such as silicon oxide, silicon nitride, silicon carbide, or silicon oxynitride. In some other embodiments, the material layer 310 includes a metal oxide such as titanium oxide or a metal nitride such as titanium nitride. In some embodiments, the material layer 310 includes a polymer, such as polyimide. In some embodiments, the material layer 310 also serves as an anti-reflection coating (ARC) layer whose composition is chosen to minimize reflectivity of radiation implemented during exposure of the photoresist layer 320. For example, in some embodiments, the material layer 310 includes silicon oxide, silicon oxygen carbide, or plasma enhanced chemical vapor deposited silicon oxide. The material layer 310 may be formed by any suitable process including CVD, PVD, plasma enhanced chemical vapor deposition (PECVD), ALD, or spin coating, and may be formed to any suitable thickness.

Referring to FIG. 3B, a photoresist layer 320 is formed over the material layer 310, in accordance with some embodiments.

The photoresist layer 320 is sensitive to radiation used during a lithography exposure process, such as DUV radiation (for example, 248 nm radiation from a KrF laser or 193 nm radiation from an ArF laser), EUV radiation (for example, 13.5 nm radiation), e-beam radiation, ion beam radiation, and/or other suitable radiation. In some embodiments, the photoresist layer 320 is sensitive to radiation having a wavelength less an about 250 nm.

The photoresist layer 320 may be formed over the material layer 310 by any suitable process. In some embodiments, the photoresist layer 320 is formed by spin coating the photoresist composition 100 onto a surface of the material layer 310. In some embodiments, the photoresist layer 320 may be formed by CVD or PVD.

In some embodiments, after spin coating the photoresist composition 100 (but before performing an exposure process), a pre-exposure bake process may be performed on the photoresist layer 320, for example, to evaporate solvent (such as solvent 330) and to densify the photoresist layer 320.

Referring to FIG. 3C, an exposure process is performed on the photoresist layer 320, where the photoresist layer 320 is illuminated with radiation. In some embodiments, the photoresist layer 320 is exposed to radiation having a wavelength less than about 250 nm, such as DUV radiation, EUV radiation, x-ray radiation, e-beam radiation, ion-beam radiation, and/or other suitable radiation. The exposure process can be in air, liquid (immersion lithography), or vacuum (for example, when implementing EUV lithography and/or e-beam lithography). In some embodiments, the radiation is patterned using a mask having an IC pattern, such that the radiation forms an image of the IC pattern on the photoresist layer 320. The mask transmits, absorbs, and/or reflects the radiation depending on the IC pattern, along with mask technologies used to fabricate the mask. Various resolution enhancement techniques, such as phase-shifting, off-axis illumination (OAI), and/or optical proximity correction (OPC), may be implemented through the mask or the exposing process. For example, OPC features may be incorporated into the IC pattern. In another example, the mask is a phase-shift mask, such as an alternative phase-shift mask, an attenuated phase-shift mask, or a chromeless phase-shift mask. In yet another example, the exposing process is implemented in an OAI mode. In some embodiments, the radiation beam is patterned by directly modulating the radiation beam according to an IC pattern without using a mask (often referred to as maskless lithography).

A latent pattern is formed on the photoresist layer 320 by the exposure process. The latent pattern generally refers to a pattern exposed on the photoresist layer 320, which eventually becomes a physical photoresist pattern when the photoresist layer 320 is subjected to a developing process. The latent pattern includes exposed portions 320A and unexposed portions 320B.

When the photoresist layer 320 is exposed to radiation, the exposed portions 320A undergo physically and/or chemically change in response to the exposure process. For example, PAGs in the exposed portions 320A of the photoresist layer 320 generate acid upon absorbing radiation, which functions as a catalyst for causing chemical reactions that increase (or decrease) solubility of the exposed portions 320A. For example, acid generated from the PAGs catalyzes cleavage of ALGs from side chain of polymer 104 in exposed portions 320A of the photoresist layer 320.

After the exposure process, a post-exposure bake (PEB) process is performed on the photoresist layer 320. The PEB process increases a temperature of the photoresist layer 320 to about 80° C. to about 180° C. In some embodiments, the PEB process is performed in a thermal chamber, increasing a temperature of the photoresist layer 320 to about 120° C. to about 150° C. During the PEB process, ALGs 114 cleave from side chains of the polymers 104 in exposed portions 320A of the photoresist layer 320, thereby chemically changing the exposed portions 320A. For example, in the depicted embodiment, the exposure process and/or the PEB process increase hydrophilicity of the exposed portions 320A (in other words, the polymers become more hydrophilic), thereby increasing solubility of the exposed portions 320A to a developer. Alternatively, in some embodiments, the exposure process and/or the PEB process decrease hydrophilicity of exposed portions 320A (in other words, the polymers become more hydrophobic), thereby decreasing solubility of the exposed portions 320A to a developer.

Referring to FIG. 3D, a developing process is performed on the photoresist layer 320, thereby forming a patterned photoresist layer 320P. In the depicted embodiment, a negative tone development (NTD) process is performed to remove unexposed portions 320B of the photoresist layer 320. For example, a NTD developer is applied to the photoresist layer 320 that dissolves the unexposed portions 320B, leaving a patterned photoresist layer 320P having openings 340 between the exposed portions 320A (collectively referred to as a photoresist pattern). In some embodiments, the NTD developer is an organic-based developer, such as n-butyl acetate (n-BA). Alternatively, a positive tone development (PTD) process is performed to remove the exposed portions 320A of the photoresist layer 320 (not shown). For example, a PTD developer is applied to the photoresist layer 320 that dissolves the exposed portions 320A, leaving a patterned photoresist layer 320P having openings 340 between unexposed portions 320B (collectively referred to as a photoresist pattern). In some embodiments, the PTD developer is an aqueous-based solvent, such as tetramethylammonium hydroxide (TMAH) or tetrabutylammonium hydroxide (TBAOH).

In embodiments of the present disclosure, by adding an etch resistance promoting group 112 between the polymer backbone 110 and the ALG 114 to minimize or eliminate the shrinkage of the photoresist layer 320, openings 340 can thus be formed by relatively smooth edges and/or sidewalls of exposed portions 320A, such that the photoresist pattern of the patterned photoresist layer 320P exhibits minimal LER/LWR and improved resist contrast, significantly enhancing lithography resolution.

In some embodiments, before developing the photoresist layer 320, a treatment is performed to the photoresist layer 320 to crosslink the photoresist layer 320, thereby reducing solubility of portions of the photoresist layer 320 to the developer. In some embodiments, the photoresist layer 320 is treated before the exposure process. In some embodiments, the photoresist layer 320 is treated after the PEB process.

Referring to FIG. 3E, the material layer 310 is etched using the patterned photoresist layer 320P as a mask to form a patterned material layer 310P, in accordance to some embodiments of the present disclosure. As a result, the pattern of the patterned photoresist layer 320P is transferred to the material layer 310.

Portions of the material layer 310 that are not covered by the patterned photoresist layer 320P are removed by a dry etching process, a wet etching process or a combination thereof. In some embodiments, the etching process includes a plasma etching process using an etchant having fluorine, such as CF, CF₂, CF₃, CF₄, C₂F₂, C₂F₃, C₃F₄, C₄F₄, C₄F₆, C₅F₆, C₆F₆, C₆F₈, or a combination thereof. Afterwards, the patterned photoresist layer 320P is removed, in accordance with some embodiments of the disclosure. In some embodiments, the patterned photoresist layer 320P is removed by ashing.

In one aspect, a method for forming a semiconductor device is provided. The methods includes forming a photoresist layer over a substrate. The photoresist layer includes a polymer and an photoacid generator (PAG). The polymer includes a polymer backbone, an etch resistance promoting group chemically bonded to the polymer backbone, and an acid labile group (ALG) chemically bonded to the etch resistance promoting group. The method further includes exposing a portion of the photoresist layer to a radiation to produce acid in exposed portion, baking the photoresist layer, resulting in cleavage of the ALG, and removing an portion of the photoresist layer to form a patterned photoresist layer.

In another aspect, a method for forming a semiconductor device is provided. The method includes depositing a material layer over a substrate, and forming a photoresist layer over the material layer. The photoresist layer includes a polymer and an photoacid generator (PAG). The polymer includes a polymer backbone, an etch resistance promoting group chemically bonded to the polymer backbone, and an acid labile group (ALG) chemically bonded to the etch resistance promoting group. The method further includes baking the photoresist layer, resulting in cleavage of the ALG, removing an portion of the photoresist layer to form a patterned photoresist layer, and etching the material layer using the patterned photoresist layer as a mask.

In still another aspect, a photoresist composition is provided. The photoresist composition includes a polymer comprising, in a polymeric form, a monomer having the following structure (II):

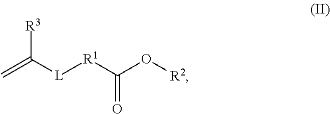

wherein:
L is a direct bond, or an alkylene, heteroalkylene, cycloalkylene ether, arylene ether, —CO—, —C(O)O—, —CONR^{a}—, —O—, —S—, —S(O)—, —SO₂— or —P(O)OH— linker;
R¹ is an etch resistance promoting group;
R² is an acid labile group;
R³ is H or an alkyl group; and
R^{a} is H or an alkyl group.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a photoresist layer over a substrate, the photoresist layer comprising a polymer and a photoacid generator (PAG), the polymer comprising a polymer backbone, an etch resistance promoting group chemically bonded to the polymer backbone, and an acid labile group (ALG) chemically bonded to the etch resistance promoting group;
exposing a portion of the photoresist layer to a radiation to produce acid in exposed portion;
baking the photoresist layer, resulting in cleavage of the ALG; and
removing a portion of the photoresist layer to form a patterned photoresist layer.

2. The method of claim 1, wherein the cleavage of the ALG forms a COOH group bonded to the etch resistance promoting group.

3. The method of claim 1, wherein the polymer comprises a monomeric unit having the following structure (I): 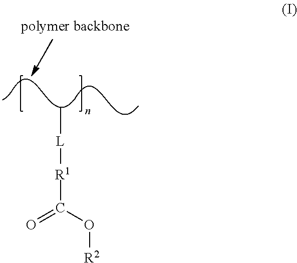
wherein:
L is a direct bond, or an alkylene, heteroalkylene, cycloalkylene ether, arylene ether, —CO—, —C(O)O—, —CONR^{a}—, —O—, —S—, —S(O)—, —SO₂— or —P(O)OH— linker;
R¹ is an etch resistance promoting group;
R² is an acid labile group;
R^{a} is H or an alkyl group; and
n is an integer of 1 to 500.

4. The method of claim 3, wherein L is —(CO)O—.

5. The method of claim 3, wherein R¹ has one of the following structures:

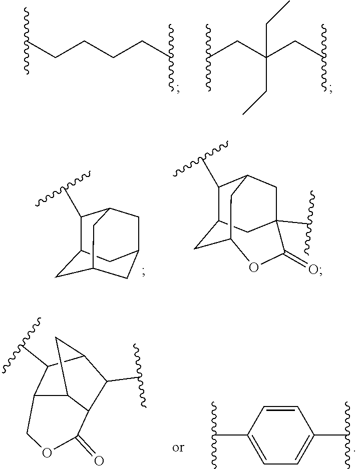

6. The method of claim 3, wherein R² has one of the following structures:

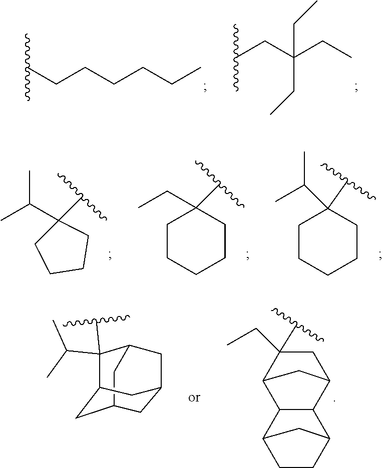

7. The method of claim 3, wherein the polymer backbone is a backbone of poly(norbornene)-co-malaic anhydride (COMA), poly(4-hydroxystyrene) (PHS), phenol-formaldehyde, polyethylene (PE), polypropylene (PP) or poly(methyl methacrylate) (PMMA).

8. The method of claim 1, wherein removing a portion of the photoresist layer comprises removing an unexposed portion of the photoresist layer using an organic-based developer.

9. The method of claim 1, wherein removing a portion of the photoresist layer comprises removing an unexposed portion of the photoresist layer using an aqueous-based developer.

10. A method for forming a semiconductor device, comprising:
depositing a material layer over a substrate;
forming a photoresist layer over the material layer, the photoresist layer comprising a polymer and a photoacid generator (PAG), the polymer comprising a polymer backbone, an etch resistance promoting group chemically bonded to the polymer backbone, and an acid labile group (ALG) chemically bonded to the etch resistance promoting group;
exposing a portion of the photoresist layer to a radiation to produce acid in exposed portion;
baking the photoresist layer, resulting in cleavage of the ALG;
removing a portion of the photoresist layer to form a patterned photoresist layer; and
etching the material layer using the patterned photoresist layer as a mask.

11. The method of claim 10, wherein the polymer comprises a monomeric unit having the following structure (I): 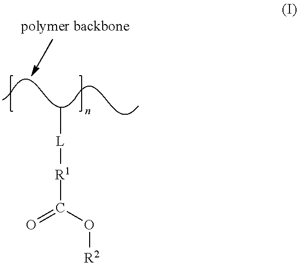
wherein:
L is a direct bond, or an alkylene, heteroalkylene, cycloalkylene ether, arylene ether, —CO—, —C(O)O—, —CONR^{a}—, —O—, —S—, —S(O)—, —SO₂— or —P(O)OH— linker;
R¹ is an etch resistance promoting group;
R² is an acid labile group;
R^{a} is H or an alkyl group; and
n is an integer of 1 to 500.

12. The method of claim 11, wherein:
L is —(CO)O—;
R¹ is an alkylene, heteroalkylene, cycloalkylene, cycloheteroalkylene or arylene group; and
R² is an alkyl, heteroalkyl, cycloalkyl or cycloheteroalkyl group.

13. The method of claim 12, wherein:
R¹ has one of the following structures: 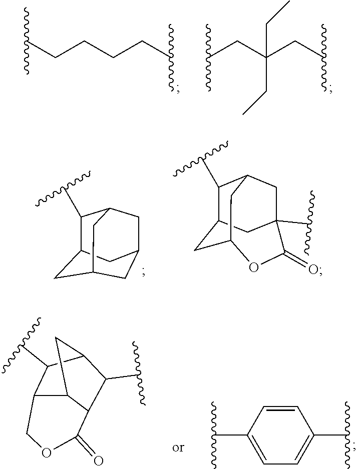
and
R² has one of the following structures:

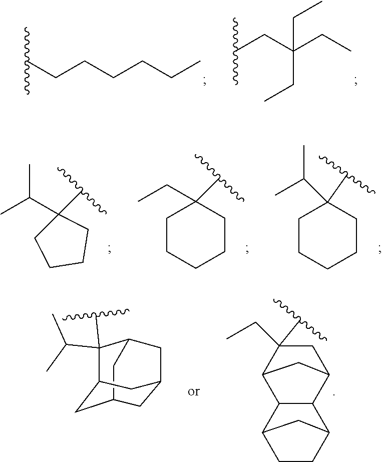

14. The method of claim 11, wherein the polymer has the following structure:

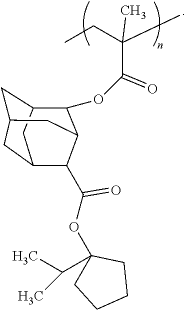

15. A photoresist composition comprising a polymer, the polymer comprising, in a polymeric form, a monomer having the following structure (II): 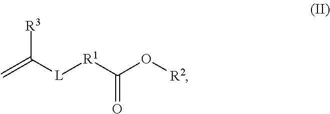
wherein:
L is a direct bond, or an alkylene, heteroalkylene, cycloalkylene ether, arylene ether, —CO—, —C(O)O—, —CONR^{a}—, —O—, —S—, —S(O)—, —SO₂— or —P(O)OH— linker;
R¹ is an etch resistance promoting group;
R² is an acid labile group;
R³ is H or an alkyl group; and
R^{a} is H or an alkyl group.

16. The photoresist composition of claim 15, wherein R¹ has one of the following structures:

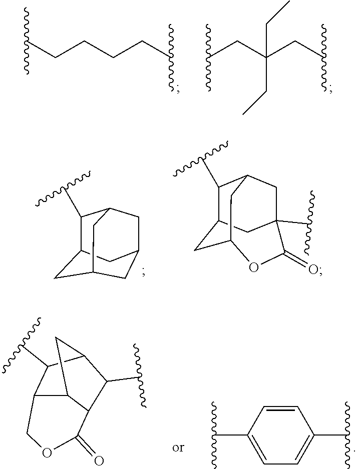

17. The photoresist composition of claim 15, wherein R² has one of the following structures:

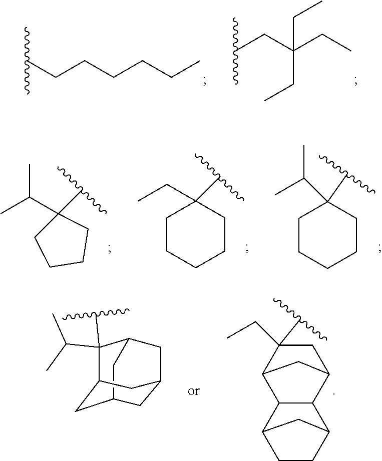

18. The photoresist composition of claim 15, wherein the monomer has the following structure:

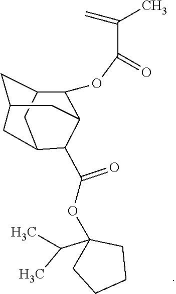 [SMILES: C=C(C)C(=O)OC1C2CC3CC(C2)C(C(=O)OC2(C(C)C)CCCC2)C1C3]

19. The photoresist composition of claim 15, further comprising a photoacid generator (PAG) that is configured to release acid in response to radiation.

20. The photoresist composition of claim 15, further comprising a solvent.
